(19) United States
(12) Patent Application Publication
(10) Pub. No.: US 2022/0293693 A1
(43) Pub. Date: Sep. 15, 2022

(54) Pixel Arrangement Structure, Electroluminescent Device and Display Device

(71) Applicant: CHONGQING KONKA PHOTOELECTRIC TECHNOLOGY RESEARCH INSTITUTE CO., LTD., Chongqing (CN)

(72) Inventor: Shanfu YUAN, Chongqing (CN)

(21) Appl. No.: 17/059,488

(22) PCT Filed: Nov. 27, 2019
(86) PCT No.: PCT/CN2019/121090

§ 371 Date: Nov. 30, 2020

(51) Int. Cl. H01L 27/32

(52) U.S. Cl. CPC H01L 27/3218; H01L 27/3216

(57) ABSTRACT

The disclosure provides a pixel arrangement structure, an electroluminescent device and a display device. The pixel arrangement structure includes: a plurality of pixel groups, wherein each pixel group includes a plurality of pixels, and adjacent pixels in each pixel group are in up-and-down staggered arrangement.

### TECHNICAL FIELD

The disclosure belongs to the technical field of display, and particularly relates to a pixel arrangement structure, an electroluminescent device and a display device.

### BACKGROUND

In recent years, electroluminescence (EL) devices have been widely used in the production of display products, for example, OLED (Organic Light-Emitting Diode), mini-LED (mini-Organic Light-Emitting Diode), and micro-LED (micro Organic Light-Emitting Diode), and as compared with conventional display products such as CRT (Cathode Ray Tube) and LCD (Liquid Crystal Display), electroluminescence devices have superior optical properties, such as high contrast, high brightness, and high color saturation, thus becoming the mainstream of next generation displays.

However, as shown in FIG. 1, in the existing display products such as mini-LEDs or micro-LEDs, pixels are in array arrangement with a close distance between adjacent pixels, and during LED transfer, if the transfer device is not accurate enough, it is prone to occur that a pixel is stuck on a previously transferred pixel, which causes reduction in the yield of LED transfer. This is especially the case for the existing display devices which are required to have a higher resolution with a smaller size, resulting in more loss in the yield of LED transfer.

Accordingly, the existing technology needs further improvement.

### SUMMARY

The first aspect of the disclosure provides a pixel arrangement structure, the pixel arrangement structure includes a plurality of pixel groups, and each pixel group of the plurality of pixel groups contains a plurality of pixels, and adjacent pixels in each pixel group of the plurality of pixel groups are in up-and-down staggered arrangement.

Optionally, the plurality of pixel groups are arranged in a pattern repeating in a vertical direction and a horizontal direction.

Optionally, the plurality of pixels include a first color pixel, a second color pixel, and a third color pixel.

Optionally, any one of the first color pixel, the second color pixel, and the third color pixel is a red pixel, a green pixel, or a blue pixel.

Optionally, a long axis of the first color pixel, a long axis of the second color pixel, and a long axis of the third color pixel are respectively parallel to a vertical direction.

Optionally, a long axis of the first color pixel is parallel to a horizontal direction; and a long axis of the second color pixel and a long axis of the third color pixel are respectively parallel to a vertical direction.

Optionally, in the same pixel group, lines connecting central points of three adjacent pixels form an equilateral triangle.

Optionally, each of the first color pixel, the second color pixel, and the third color pixel is a polygon with four or more sides.

Optionally, each pixel corresponds to a pixel region, and a width of the first color pixel, a width of the second color pixel, and a width of the third color pixel are respectively less than half of a width of the pixel region; and a length of the first color pixel, a length of the second color pixel, and a length of the third color pixel are respectively less than a horizontal distance between the second color pixel and the third color pixel.

Optionally, the pixel group includes a first sub pixel group and a second sub pixel group.

Optionally, each of the first sub pixel group and the second sub pixel group includes a first color pixel, a second color pixel, and a third color pixel.

Optionally, lines connecting central points of the pixels in the first sub pixel group form a first equilateral triangle; and lines connecting central points of the pixels in the second sub pixel group form a second equilateral triangle.

Optionally, the pixels in the first sub pixel group are in mirror symmetry with the pixels in the second sub pixel group.

The second aspect of the disclosure provides an electroluminescent device including a substrate and the pixel arrangement structure on the substrate.

The third aspect of the disclosure provides a display device including the electroluminescent device.

### BRIEF DESCRIPTION OF THE DRAWINGS

FIG. 1 is a schematic diagram showing partial layout of a pixel arrangement structure in the prior art;

FIG. 2 is a schematic diagram showing partial layout of a pixel arrangement structure of embodiment 1 of the disclosure, with a long axis of a first color pixel parallel to a vertical direction;

FIG. 3 is a schematic diagram showing partial layout of a pixel arrangement structure of embodiment 1 of the disclosure, with a long axis of a first color pixel parallel to a horizontal direction;

FIG. 4 is a schematic diagram showing partial layout of a pixel arrangement structure of embodiment 1 of the disclosure, with pixels shaped as octagons;

FIG. 5 is a schematic diagram showing partial layout of a pixel arrangement structure of embodiment 2 of the disclosure, with a long axis of a first color pixel parallel to the vertical direction and pixels shaped as quadrilaterals;

FIG. 6 is a schematic diagram showing partial layout of a pixel arrangement structure of embodiment 2 of the disclosure, with a long axis of a first color pixel parallel to the vertical direction and the pixels shaped as octagons;

FIG. 7 is a schematic diagram showing partial layout of a pixel arrangement structure of embodiment 2 of the disclosure, with a long axis of a first color pixel parallel to the horizontal direction and pixels shaped as quadrilaterals; and

FIG. 8 is a schematic diagram showing partial layout of a pixel arrangement structure of embodiment 2 of the disclosure, with a long axis of a first color pixel parallel to the horizontal direction and pixels shaped as octagons.

### DETAILED DESCRIPTION OF THE EMBODIMENTS

In order that the objects, technical schemes, and advantages of the disclosure will become more apparent and clearer, the disclosure will be described in further detail hereinafter with reference to the drawings and in conjunction with embodiments. It is to be understood that the embodiments described herein are merely illustrative of the disclosure and are not intended to be limiting thereof.

As shown in FIG. 1, in the existing display products, RGB pixels are alternatively arranged in an array structure with a close distance between adjacent pixels, and during LED transfer, if the transfer device is not accurate enough, it is prone to occur that a pixel is stuck on a previously transferred adjacent pixel, which causes reduction in the yield of LED transfer. In order to solve the above problems, the disclosure provides a pixel arrangement structure for an electroluminescent device of a display device, which is applicable as a pixel arrangement structure of, for example, a display panel or a backplane of the electroluminescent device. In some embodiments, the pixel arrangement structure is applied to a display panel, and the pixel structure of the display panel includes: a plurality of pixel groups; and each pixel group of the plurality of pixel groups includes a plurality of pixels, and adjacent pixels in each pixel group are in up-and-down staggered arrangement. As in each pixel group, each pixel and its adjacent pixels are in up-and-down staggered arrangement, so that the distance between the pixel and its adjacent pixels is increased, thereby the yield of LED transfer is improved.

In some embodiments, the plurality of pixel groups are arranged in a pattern repeating in both a vertical direction and a horizontal direction. The plurality of pixels include a first color pixel, a second color pixel, and a third color pixel. In some embodiments, any one of the first color pixel, the second color pixel, and the third color pixel is a red pixel, a green pixel, or a blue pixel.

In some embodiment, the pixel group includes three pixels of different colors, i.e. a first color pixel, a second color pixel and a third color pixel, wherein a center point of the second color pixel and a center point of the third color pixel are on the same line, and the second color pixel and the third color pixel are arranged symmetrical about a central axis. The first color pixel, and the second color pixel and the third color pixel are in up-and-down staggered arrangement, and the center point of the first color pixel is on a symmetrical axis of the second color pixel and the third color pixel. Lines connecting the central points of the adjacent three pixels of different colors in the pixel group form an equilateral triangle, so that the pixels in the pixel group are arranged as staggered points, and the distance between the adjacent pixels is increased. Therefore, crosstalk does not occur between the adjacent pixels, and the luminous area is maximized.

In some embodiments, a long axis of the first color pixel, a long axis of the second color pixel and a long axis of the third color pixel are parallel to the vertical direction. Although the distance between the pixels in the pixel group can be increased by the up-and-down staggered arrangement of the pixels, a distance between one end, close to the second color pixel, of the first color pixel, and the second color pixel is still small, a distance between one end, close to the third color pixel, of the first color pixel, and the third color pixel is still small. In order to further increase the distance between the pixels, in some other embodiments, the first color pixel is rotated 90° clockwise or 270° counterclockwise to make its long axis parallel to the horizontal direction, so that the distance between one end, close to the second color pixel, of the first color pixel, and the second color pixel is increased, and the distance between one end, close to the third color pixel, of the first color pixel, and the third color pixel is increased, thereby the yield of LED transfer is improved.

In implementation, for the pixel group composed of the first color pixel, the second color pixel and the third color pixel, although the distance between the pixels in the pixel group can be increased, the distance between some pixels of adjacent pixel groups is still close. To further increase the distance between the pixels of the pixel groups, in this embodiment, the pixel group is divided into a first sub pixel group and a second sub pixel group. Each of the first sub pixel group and the second sub pixel group includes a first color pixel, a second color pixel, and a third color pixel, and the pixels in the first sub pixel group are in mirror symmetry with the pixels in the second sub pixel group, so that the pixels in adjacent pixel groups are also in up-and-down staggered arrangement, and the distance between a pixel and its adjacent pixels is further increased, thereby the yield of LED transfer yield is improved.

In some embodiments, in order to further increase the distance between the pixels, the first color pixel, the second color pixel, and the third color pixel can be quadrangles or any other polygons with more than four sides, such as pentagons, hexagons or octagons, so that the distance between the corners of the pixels is further increased to facilitate LED pixel transfer, thereby the yield of LED transfer is improved.

In some embodiments, each pixel group of the plurality of pixel groups corresponds to a pixel region, so that on the basis of improving the yield of LED transfer, image crosstalk caused by mutual influence between adjacent pixels is prevented; and in these embodiment, a width of the first color pixel, a width of the second color pixel, and a width of the third color pixel are respectively less than half of a width of the pixel region; and a length of the first color pixel, a length of the second color pixel and a length of the third color pixel are respectively less than a horizontal distance between the second color pixel and the third color pixel.

In some embodiments, the disclosure further provides an electroluminescent device including a substrate and the pixel arrangement structure according to afore-mentioned embodiments of the disclosure on the substrate.

In some embodiments, the disclosure further provides a display device including the electroluminescent device according to the afore-mentioned embodiments of the disclosure.

The disclosure will now be further described with reference to the accompanying drawings and embodiments.

### Embodiment 1

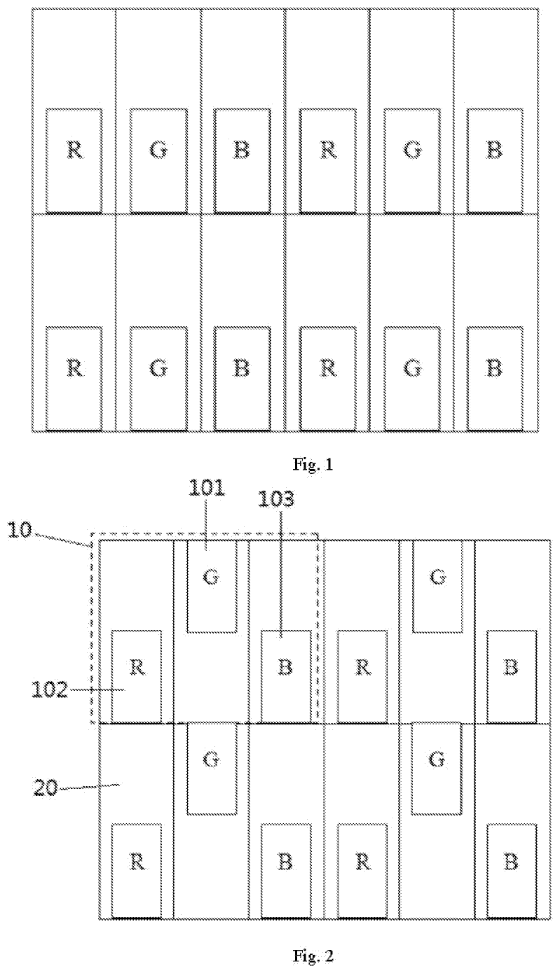

Referring to FIGS. 2 to 4, schematic diagrams illustrating partial layout of a pixel arrangement structure of embodiment 1 of the disclosure are shown. As shown in FIG. 2, a pixel structure of a display panel includes: a plurality of pixel groups 10; wherein the pixel group 10 includes a first color pixel 101, a second color pixel 102, and a third color pixel 103. Adjacent pixels of the first color pixel 101, the second color pixel 102 and the third color pixel 103 are in up-and-down staggered arrangement, that is, adjacent pixels are not one the same straight line, so that the distance between adjacent pixels in the same pixel group 10 is increased, thereby the yield of LED transfer is improved.

Still referring to FIG. 2, in the pixel arrangement structure of this embodiment, the plurality of pixel groups 10 are arranged in a pattern repeating in a vertical direction and a horizontal direction. The first color pixel 101 is a red pixel, the second color pixel 102 is a green pixel, and the third color pixel 103 is a blue pixel.

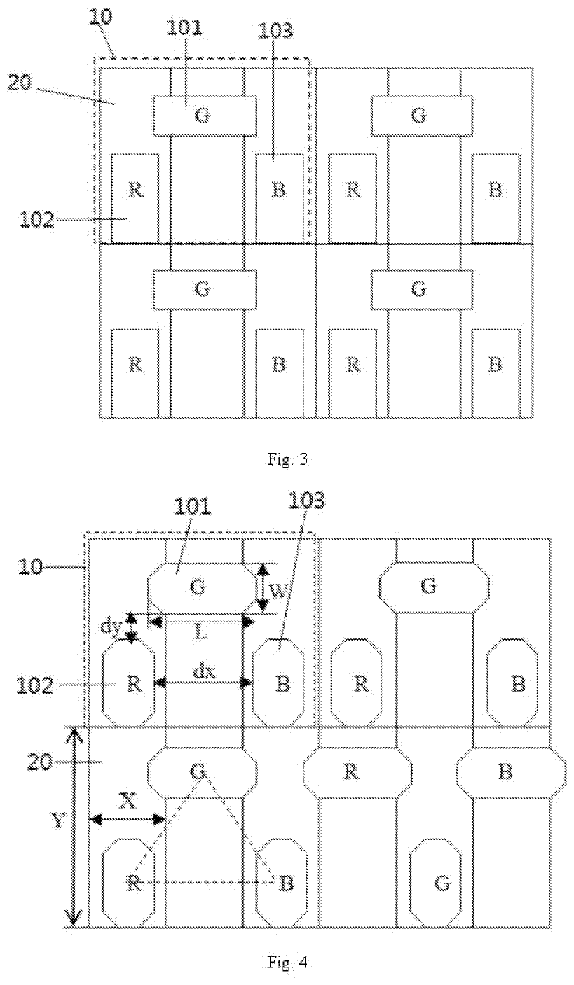

In implementation, as shown in FIG. 2, a long axis of the first color pixel 101, a long axis of the second color pixel 102 and a long axis of the third color pixel 103 are respectively parallel to the vertical direction. Although the distance between the pixels can be increased by the staggered arrangement of adjacent pixels, the distance between one end, close to the second color pixel 102, of the first color pixel 101, and the second color pixel 102 is still small, the distance between one end, close to the third color pixel 103, of the first color pixel 101, and the third color pixel 103 is still small. To further increase the distance between adjacent pixels, in this embodiment, the first color pixel 101 is rotated 90° clockwise or 270° counterclockwise to obtain a pixel arrangement structure as shown in FIG. 3.

Referring to FIG. 3, particularly, a long axis of the first color pixel 101 is changed from being parallel to the vertical direction to being parallel the horizontal direction, and a long axis of the second color pixel 102 and a long axis of the third color pixel 103 remain being parallel to the vertical direction. The first color pixel 101, the second color pixel 102, and the third color pixel 103 are respectively within a pixel region 20, and in connection with FIG. 4, it is assumed that the pixel region 20 has a length of Y, and the color pixels have a length of L and a width of W. In the pixel arrangement structure of this embodiment as shown in FIGS. 3 and 4, the distance from the bottom of the first color pixel 101 to the top of the second color pixel 102 and the distance from the bottom of the first color pixel 101 to the top of the third color pixel 103 are respectively dy=Y−L−L/2−W/2, while in the pixel arrangement structure as shown in FIG. 2, the distance from the bottom of the first color pixel 101 to the top of the second color pixel 102 and the distance from the bottom of the first color pixel 101 to the top of the third color pixel 103 are respectively dy=Y−2L. As the length L of the color pixels is greater than the width W, the distance from the bottom of the first color pixel 101 to the top of the second color pixel 102 and the distance from the bottom of the first color pixel 101 to the top of the third color pixel 103 in FIGS. 3 and 4 are greater than the corresponding distance in FIG. 2, so that the distance between adjacent pixels in the pixel group 10 is further increased, thereby the yield of LED transfer is improved.

Referring further to FIG. 4, in order to increase the distance between any two of the adjacent first color pixel 101, second color pixel 102, and third color pixel 103, the shapes of the first color pixel 101, the second color pixel 102 and the third color pixel 103 may be quadrangles or any other polygons with more than four sides, such as pentagons, hexagons or octagons. In this embodiment, particularly, the first color pixel, the second color pixel and the third color pixel are octagons, which may be regular octagons or irregular octagons.

Still referring to FIG. 4, the shape of the first color pixel 101, the shape of the second color pixel 102, and the shape of the third color pixel 103 are same, and the length of each pixel is L and the width of each pixel is W, the distance from the bottom of the first color pixel 101 to the top of the second color pixel 102 and the distance from the bottom of the first color pixel 101 to the top of the third color pixel 103 are respectively dy, the horizontal distance between the second color pixel 102 and the third color pixel 103 is dx, and a width of the pixel region 20 corresponding to each pixel is X. When the distances dx and dy between the pixels are both greater than the width X of the pixel region 20, crosstalk does not occur between the pixels. In this embodiment, when the width W of the first color pixel 101, the width W of the second color pixel 102 and the width W of the third color pixel 103 is less than half of the width X of the pixel region 20, the horizontal distance dx between the pixels in the same pixel group is dx=3X−2W>X, and the distance between adjacent pixels of adjacent pixel groups is 2X−2W>X, that is, it is satisfied that the horizontal distance between any two pixels is greater than the width of the pixel region 20. The distance from the bottom of the first color pixel 101 to the top of the second color pixel 102 and the distance from the bottom of the first color pixel 101 to the top of the third color pixel 103 are respectively dy=Y−W−L, assuming that Y=3X, then dy=Y−W−L=3X−W−L<X, namely L<2X−W, and dx=2X−W, that is, when the length of the pixels is less than the horizontal distance between the second color pixel and the third color pixel, it is satisfied that the vertical distance between any two pixels is greater than the width of the pixel region 20, so that crosstalk between the pixels is prevented, thereby the yield of LED transfer is improved.

Still referring to FIG. 4, the pixel group 10 includes three pixels of different colors, i.e. the first color pixel 101, the second color pixel 102, and the third color pixel 103, and lines connecting a central point of the first color pixel 101, a central point of the second color pixel 102, and a central point of the third color pixel 103 form an equilateral triangle, so that the pixels in the pixel group are arranged as staggered points, and the distance between the adjacent pixels is increased. Therefore, crosstalk does not occur between the adjacent pixels, and the luminous area can be maximized.

### Embodiment 2

Referring to FIGS. 5 to 8, schematic diagrams illustrating partial layout of a pixel arrangement structure of embodiment 2 of the disclosure are shown. In this embodiment, a pixel structure of a display panel includes: a plurality of pixel groups 10; and the pixel group 10 includes a first color pixel 101, a second color pixel 102 and a third color pixel 103. Adjacent pixels of the first color pixel 101, the second color pixel 102 and the third color pixel 103 are in up-and-down staggered arrangement, that is, adjacent pixels are not on the same straight line, so that the distance between adjacent pixels in the same pixel group 10 is increased, thereby the yield of LED transfer is improved.

Still referring to FIGS. 5 to 8, the pixel group 10 includes a first sub pixel group 11 and a second sub pixel group 12. The first sub pixel group 11 includes a first color pixel 101, a second color pixel 102, and a third color pixel 103. The second sub pixel group 12 also includes a first color pixel 101, a second color pixel 102, and a third color pixel 103. Furthermore, the pixels in the first sub pixel group 11 are in mirror symmetry with the pixels in the second sub pixel group 12.

Still referring to FIGS. 5 to 8, in the pixel arrangement structure of this embodiment, the plurality of first sub pixel groups 11 and the plurality of second sub pixel groups 12 are respectively arranged in a pattern repeating in a vertical direction, that is the first sub pixel groups 11 and the second sub pixel groups 12 repeat respectively in the vertical direction and respectively form a column. The first sub pixel groups 11 and the second sub pixel groups 12 are arranged side by side in the horizontal direction. The first color pixel 101, the second color pixel 102 and the third color pixel 103 contained in each of the first sub pixel group 11 and the second sub pixel group 12 also may be any one of a red pixel, a green pixel, or a blue pixel.

Referring to FIG. 5, particularly, the arrangement structure of the color pixels in the first sub pixel group 11 is as same as the arrangement structure of the color pixels in a single pixel group 10 of FIG. 2, while the difference is that in this embodiment, the second sub pixel group 12 containing color pixels in mirror symmetry with the color pixels in the first sub pixel group 11 is added on the basis of the first sub pixel group 11, so that not only are the color pixels in the single pixel group 10 in up-and-down staggered arrangement, but the color pixels of adjacent pixel groups 10 are also in up-and-down staggered arrangement, so that the distance between adjacent pixels is further increased on the basis of embodiment 1, thereby the yield of LED transfer is improved.

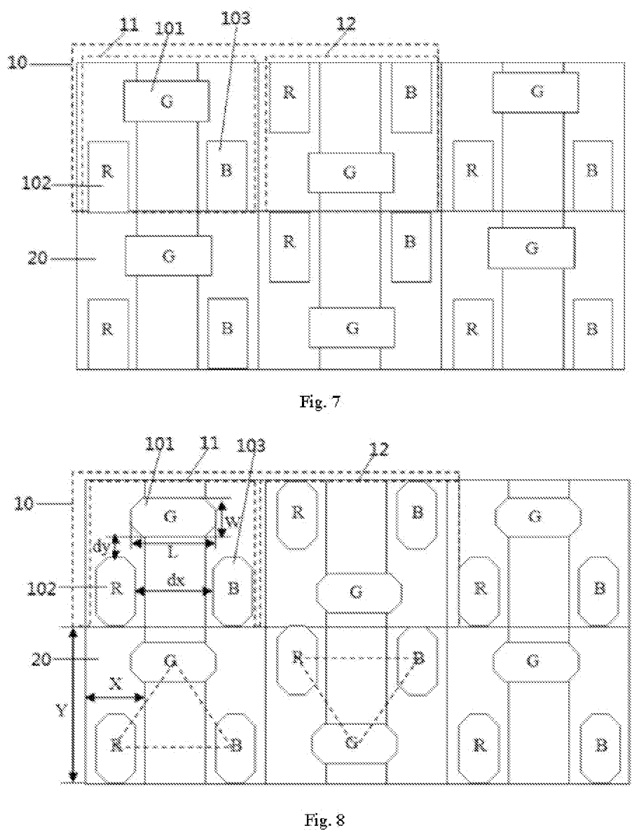

In implementation, as shown in FIG. 5, a long axis of the first color pixel 101, a long axis of the second color pixel 102 and a long axis of the third color pixel 103 are respectively parallel to the vertical direction. Although the distance between the pixels can be increased by the staggered arrangement of adjacent pixels, the distance between one end, close to the second color pixel 102, of the first color pixel 101, and the second color pixel 102 is still small, the distance between one end, close to the third color pixel 103, of the first color pixel 101, and the third color pixel 103 is still small. To further increase the distance between adjacent pixels, similar to embodiment 1, in this embodiment, the first color pixel 101 is rotated 90° clockwise or 270° counterclockwise to obtain a pixel arrangement structure as shown in FIG. 7.

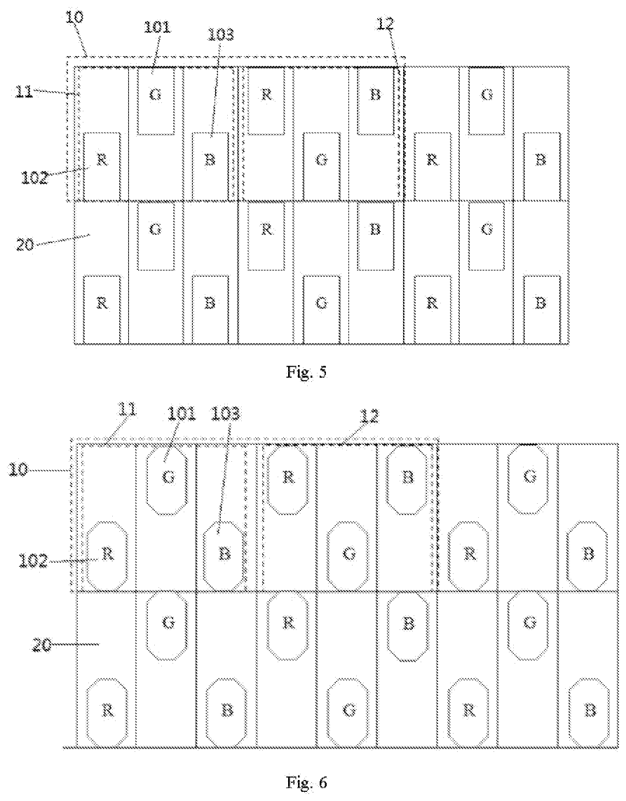

Referring to FIG. 7, particularly, a long axis of the first color pixel 101 is changed from being parallel to the vertical direction to being parallel the horizontal direction, and a long axis of the second color pixel 102 and a long axis of the third color pixel 103 remain being parallel to the vertical direction. The first color pixel 101, the second color pixel 102, and the third color pixel 103 are respectively within a pixel region 20, and it is assumed that a length of the pixel region 20 is Y, and a length of each color pixels is L and a width of each color pixels is W. Similar to embodiment 1, as shown in FIGS. 6 and 7, the distance from the bottom of the first color pixel 101 to the top of the second color pixel 102 and the distance from the bottom of the first color pixel 101 to the top of the third color pixel 103 are respectively dy=Y−L−L/2−W/2, while in the pixel arrangement structure as shown in FIG. 5, the distance from the bottom of the first color pixel 101 to the top of the second color pixel 102 and the distance from the bottom of the first color pixel 101 to the top of the third color pixel 103 are respectively dy=Y−2L. As the length L of the color pixels is greater than the width W, the distance from the bottom of the first color pixel 101 to the top of the second color pixel 102 and the distance from the bottom of the first color pixel 101 to the top of the third color pixel 103 in FIGS. 6 and 7 are respectively greater than the corresponding distance in FIG. 5, so that the distance between adjacent pixels in the pixel group 10 is further increased, thereby the yield of LED transfer is improved.

Referring further to FIGS. 5 to 8, in order to increase the distance between any two of the adjacent first color pixel 101, second color pixel 102, and third color pixel 103, the shape of the first color pixel 101, the shape of the second color pixel 102 and the shape of the third color pixel 103 may be quadrangles or any other polygons with more than four sides. In this embodiment, particularly, the first color pixel, the second color pixel and the third color pixel are octagons, which may be regular octagons or irregular octagons.

Referring to FIG. 8, particularly, in the first sub pixel group 11, center points of the second color pixel 102 and the third color pixel 103 are on the same line, and the second color pixel 102 and the third color pixel 103 are arranged symmetrical about a central axis; a center point of the first color pixel 101 is on the central axis of the second color pixel 102 and the third color pixel 103, and lines connecting the central points of the first color pixel 101, the second color pixel 102 and the third color pixel 103 form a first equilateral triangle. Similar to the pixel structure in the first sub pixel group 11, in the second sub pixel group 12, center points of the second color pixel 102 and the third color pixel 103 are on the same line, a center point of the first color pixel 101 is on the central axis of the second color pixel 102 and the third color pixel 103, and lines connecting the central points of the first color pixel 101, the second color pixel 102 and the third color pixel 103 in the second sub pixel group 12 form an inverted equilateral triangle opposite to the equilateral triangle of the first sub pixel group 11, the inverted equilateral triangle is a second equilateral triangle.

Still referring to FIG. 8, the shape of the first color pixel 101, the shape of the second color pixel 102, and the shape of the third color pixel 103 are same, a length of each pixel is L and a width of each pixel is W, the distance from the bottom of the first color pixel 101 to the top of the second color pixel 102 and the distance from the bottom of the first color pixel 101 to the top of the third color pixel 103 are respectively dy, the horizontal distance between the second color pixel 102 and the third color pixel 103 is dx, and the width of the pixel region 20 corresponding to each pixel is X. When the distances dx and dy between the pixels are both greater than the width X of the pixel region 20, crosstalk does not occur between the pixels. In this embodiment, when the width W of the first color pixel 101, the width W of the second color pixel 102 and the width W of the third color pixel 103 is less than half of the width X of the pixel region 20 and the length L is less than the horizontal distance between the second color pixel and the third color pixel, the horizontal distance dx between the pixels in the same pixel group is dx=3X−2W>X, and the distance between adjacent pixels of adjacent pixel groups is 3X−W−L>X, that is, it is satisfied that the horizontal distance between any two pixels is greater than the width of the pixel region 20. The distance from the bottom of the first color pixel 101 to the top of the second color pixel 102 and the distance from the bottom of the first color pixel 101 to the top of the third color pixel 103 are respectively dy=Y−W−L, assuming that Y=3X, then dy=Y−W−L=3X−W−L<X, namely L<2X−W, and dx=2X−W, that is, when the length of the pixels is less than the horizontal distance between the second color pixel and the third color pixel, it is satisfied that the vertical distance between any two pixels is greater than the width of the pixel region 20, so that crosstalk between the pixels is prevented, thereby the yield of LED transfer is improved.

In summary, the disclosure provides a pixel arrangement structure, an electroluminescent device and a display device. The pixel arrangement structure includes a plurality of pixel groups, wherein each pixel group contains a plurality of pixels, and adjacent pixels in each pixel group are in up-and-down staggered arrangement. According to the present disclosure, pixels are grouped into a plurality of pixel groups in which adjacent pixels in each pixel group are in up-and-down staggered arrangement, and the shapes and the directions of long axes of the pixels are changed, so that the distance between adjacent pixels in a single pixel group is increased; and the sub pixel groups are arranged in mirror symmetry, so that the distance between pixels in adjacent pixel groups is increased, thereby the yield of LED transfer is improved, and meeting the demands for smaller size and higher resolution of electroluminescent display devices.

It is to be understood that the system application of the present invention is not limited to the examples described above, and that modifications and variations may be resorted to in light of the above teachings by those of ordinary skill in the art, all falling within the scope of the appended claims.

What is claimed is:

1. A pixel arrangement structure, comprising: a plurality of pixel groups, wherein each pixel group of the plurality of pixel groups comprises a plurality of pixels, and adjacent pixels in each pixel group of the plurality of pixel groups are in up-and-down staggered arrangement.

2. The pixel arrangement structure as claimed in claim 1, wherein the plurality of pixel groups are arranged in a pattern repeating in a vertical direction and a horizontal direction.

3. The pixel arrangement structure as claimed in claim 1, wherein the plurality of pixels comprise a first color pixel, a second color pixel, and a third color pixel.

4. The pixel arrangement structure as claimed in claim 3, wherein any one of the first color pixel, the second color pixel, and the third color pixel is a red pixel, a green pixel, or a blue pixel.

5. The pixel arrangement structure as claimed in claim 4, wherein a long axis of the first color pixel, a long axis of the second color pixel, and a long axis of the third color pixel are respectively parallel to a vertical direction.

6. The pixel arrangement structure as claimed in claim 4, wherein a long axis of the first color pixel is parallel to a horizontal direction; and a long axis of the second color pixel and a long axis of the third color pixel are respectively parallel to a vertical direction.

7. The pixel arrangement structure as claimed in claim 4, wherein in the same pixel group, lines connecting central points of three adjacent pixels form an equilateral triangle.

8. The pixel arrangement structure as claimed in claim 4, wherein each of the first color pixel, the second color pixel, and the third color pixel is a polygon with four or more sides.

9. The pixel arrangement structure as claimed in claim 4, wherein each pixel corresponds to a pixel region, and a width of the first color pixel, a width of the second color pixel, and a width of the third color pixel are respectively less than half of a width of the pixel region; and a length of the first color pixel, a length of the second color pixel, and a length of the third color pixel are respectively less than a horizontal distance between the second color pixel and the third color pixel.

10. The pixel arrangement structure as claimed in claim 1, wherein the pixel group includes a first sub pixel group and a second sub pixel group.

11. The pixel arrangement structure as claimed in claim 10, wherein each of the first sub pixel group and the second sub pixel group comprises a first color pixel, a second color pixel, and a third color pixel.

12. The pixel arrangement structure as claimed in claim 11, wherein lines connecting central points of the pixels in the first sub pixel group form a first equilateral triangle; and lines connecting central points of the pixels in the second sub pixel group form a second equilateral triangle.

13. The pixel arrangement structure as claimed in claim 12, wherein the pixels in the first sub pixel group are in mirror symmetry with the pixels in the second sub pixel group.

14. An electroluminescent device comprising a substrate and the pixel arrangement structure as claimed in claim 1 on the substrate.

15. A display device comprising the electroluminescent device as claimed in claim 14.

16. The electroluminescent device as claimed in claim 14, wherein the plurality of pixel groups are arranged in a pattern repeating in a vertical direction and a horizontal direction.

17. The electroluminescent device as claimed in claim 14, wherein the plurality of pixels comprise a first color pixel, a second color pixel, and a third color pixel.

18. The electroluminescent device as claimed in claim 17, wherein any one of the first color pixel, the second color pixel, and the third color pixel is a red pixel, a green pixel, or a blue pixel.

19. The electroluminescent device as claimed in claim 18, wherein a long axis of the first color pixel, a long axis of the second color pixel, and a long axis of the third color pixel are respectively parallel to a vertical direction.

20. The electroluminescent device as claimed in claim 18, wherein a long axis of the first color pixel is parallel to a horizontal direction; and a long axis of the second color pixel and a long axis of the third color pixel are respectively parallel to a vertical direction.
